(19) United States
(12) Patent Application Publication
(10) Pub. No.: US 2017/0016952 A1
(43) Pub. Date: Jan. 19, 2017

(54) Electronic Component Testing

(71) Applicant: Schlumberger Technology Corporation, Sugar Land, TX (US)

(72) Inventors: Robson Ladeia Serafim, Sugar Land, TX (US); Fei Song, Stafford, TX (US); Ahed Qaddoura, Sugar Land, TX (US); Francis Dupouy, Cheltenham (GB); Robert Hender Kelly, Houston, TX (US)

(21) Appl. No.: 14/801,373

(22) Filed: Jul. 16, 2015

(51) Int. Cl. G01R 31/28

(52) U.S. Cl. CPC G01R 31/2817

(57) ABSTRACT

A fixture for connecting a printed wiring assembly (PWA) to an acceleration table for subjecting the PWA to highly accelerated stress screen (HASS) testing. The fixture comprises a member and multiple spacers. First openings extend through the member for receiving fasteners to connect the member to the acceleration table such that the member is spaced from the acceleration table. Second openings extend into the member for receiving fasteners to connect the PWA to the member. A third opening extends through the member to expose a substantial portion of a surface of the PWA. Also disclosed is a method comprising selecting a PWA for HASS testing, determining which one of a plurality of predetermined PWA categories includes the selected PWA, and conducting the HASS test on the selected PWA utilizing HASS testing parameters associated with the determined PWA category.

### BACKGROUND OF THE DISCLOSURE

Wells are generally drilled into a land surface or ocean bed to recover natural deposits of oil and gas, as well as other natural resources that are trapped in geological formations in the Earth's crust. Testing and evaluation of completed and partially finished wellbores has become commonplace, such as to increase well production and return on investment. Information about the subsurface formations, such as measurements of the formation pressure, formation permeability, and recovery of formation fluid samples, may be utilized for predicting the economic value, the production capacity, and the production lifetime of a subsurface formation. Downhole tools, such as formation testers, may perform evaluations in real-time during sampling of the formation fluid.

These testing and evaluation operations have become increasingly expensive as wellbores are drilled deeper and through more difficult materials. In working with deeper and more complex wellbores, it becomes more likely that downhole tools may include numerous testing, navigation, and/or other electronic components comprising printed wiring assemblies (PWAs). The PWAs are subjected to high temperatures from the well environment. Some PWAs also generate high quantities of heat, substantially raising their temperature. Excessive temperatures shorten the life of the PWAs, especially when internal temperatures exceed functional temperature limits of the PWAs. The PWAs are also subjected to a variety of loads, including pressure differentials, tension, compression, torsion, bending, shock, and vibrations. Shock and vibration loads are especially damaging to the PWAs.

### SUMMARY OF THE DISCLOSURE

This summary is provided to introduce a selection of concepts that are further described below in the detailed description. This summary is not intended to identify indispensable features of the claimed subject matter, nor is it intended for use as an aid in limiting the scope of the claimed subject matter.

The present disclosure introduces an apparatus that includes a fixture for connecting a PWA to an acceleration table for subjecting the PWA to highly accelerated stress screen (HASS) testing. The fixture includes a member and multiple spacers. First openings extend through the member and corresponding ones of the spacers for receiving first fasteners connecting the member and the spacers to the acceleration table such that the member is spaced from the acceleration table by the spacers. Second openings extend into the member for receiving second fasteners connecting the PWA to the member. A third opening disposed between ones of the second openings extends through the member and exposes a substantial portion of a surface of the PWA facing the acceleration table.

The present disclosure also introduces an apparatus that includes a fixture for connecting a PWA to an acceleration table for subjecting the PWA to HASS testing, where the fixture includes a base having a length, a width, and a height. The base includes openings for receiving fasteners connecting the base to the acceleration table. The fixture also includes a first plate fixedly disposed relative to the base and elongated in a direction extending along the length of the base. The fixture also includes a second plate slidably disposed relative to the base and elongated in a direction extending along the length of the base. The second plate is movable toward and away from the first plate. The fixture also includes elongated spacers each extending in a direction along the width of the base between the base and the first and second plates for maintaining the first and second plates spaced from the base. The elongated spacers are fixedly connected with respect to the base and the first plate. The fixture also includes a clamp operable to retain the PWA between the first and second plates.

The present disclosure also introduces a method that includes selecting a PWA for a HASS test, determining which one of predetermined PWA categories includes the selected PWA, and conducting the HASS test on the selected PWA utilizing HASS testing parameters associated with the determined PWA category.

These and additional aspects of the present disclosure are set forth in the description that follows, and/or may be learned by a person having ordinary skill in the art by reading the materials herein and/or practicing the principles described herein. At least some aspects of the present disclosure may be achieved via means recited in the attached claims.

### BRIEF DESCRIPTION OF THE DRAWINGS

The present disclosure is understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is an expanded view of at least a portion of apparatus according to one or more aspects of the present disclosure.

FIG. 2 is a perspective view of the apparatus shown in FIG. 1 according to one or more aspects of the present disclosure.

FIG. 3 is a perspective view of at least a portion of an apparatus according to one or more aspects of the present disclosure.

FIG. 4 is a perspective view of an example implementation of the apparatus shown in FIGS. 1 and 2 according to one or more aspects of the present disclosure.

FIG. 5 is a perspective view of an example implementation of the apparatus shown in FIG. 3 according to one or more aspects of the present disclosure.

FIG. 6 is a perspective view of at least a portion of an apparatus according to one or more aspects of the present disclosure.

FIG. 7 is a side view of the apparatus shown in FIG. 6 according to one or more aspects of the present disclosure.

FIG. 8 is a top view of the apparatus shown in FIG. 6 according to one or more aspects of the present disclosure.

FIGS. 9-12 are side views of apparatus related to one or more aspects of the present disclosure.

FIG. 13 is graphs related to one or more aspects of the present disclosure.

FIG. 14 is a flow-chart diagram of at least a portion of a method according to one or more aspects of the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for simplicity and clarity, and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

PWA failures generally fall into three classes: early life failures (i.e., infant mortality), random failures, and wear-out failures. Early life failures of PWAs are generally attributable to design mistakes and/or immaturity of manufacturing processes, resulting in latent defects that are not found prior to installation and field use. Such latent defects may cause the PWAs to fail shortly after being subjected to operational demands and the severity of the downhole environment.

Highly accelerated stress screen (HASS) testing reduces early life PWA failures prior to installation and field use, thereby improving product quality and reliability. HASS testing also works as a quality control method to oversee manufacturer process variation and to weed out production induced defects without substantially reducing product life. HASS testing utilizes rapid temperature transitions combined with multi-axis vibration or acceleration, such as may be applied by an acceleration table or a highly accelerated life test (HALT) machine, to uncover latent defects induced by the manufacturing process, and to reveal defects that would normally remain undetected during downhole tool assembly.

The present disclosure introduces apparatus and methods developed to improve the quality of the PWAs installed in downhole tools. For example, the present disclosure introduces mounting fixtures for securing or otherwise connecting PWAs to an acceleration table of a HALT machine or another testing machine. The mounting fixtures may facilitate transfer of vibration or acceleration energy to the PWAs while simultaneously facilitating uniform heat transfer to both sides (top and bottom) of the PWAs during HASS testing. One or more aspects of the apparatus and/or methods introduced in the present disclosure may be utilized to identify infant mortality failures by introducing the PWAs to different stress profiles in the form of vibration or acceleration and temperature fluctuations for different predefined PWA categories, thus, enhancing quality and reliability of downhole electronics. The PWAs may be separated among predetermined PWA categories based on component technology or type, mounting type, and/or PWA specifications. The methodology may be utilized for screening the PWAs utilizing HASS testing parameters that correspond to the different PWA categories.

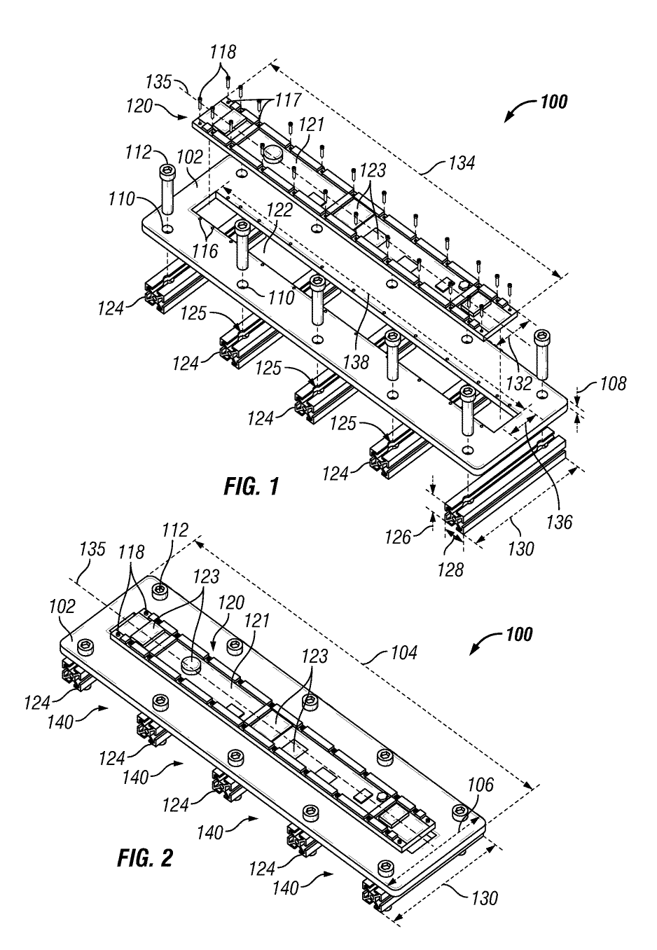

FIG. 1 is an expanded view of at least a portion of a fixture 100 and a PWA 120 according to one or more aspects of the present disclosure. FIG. 2 is a perspective view of the PWA 120 connected with the fixture 100 according to one or more aspects of the present disclosure. The following description refers to FIGS. 1 and 2, collectively.

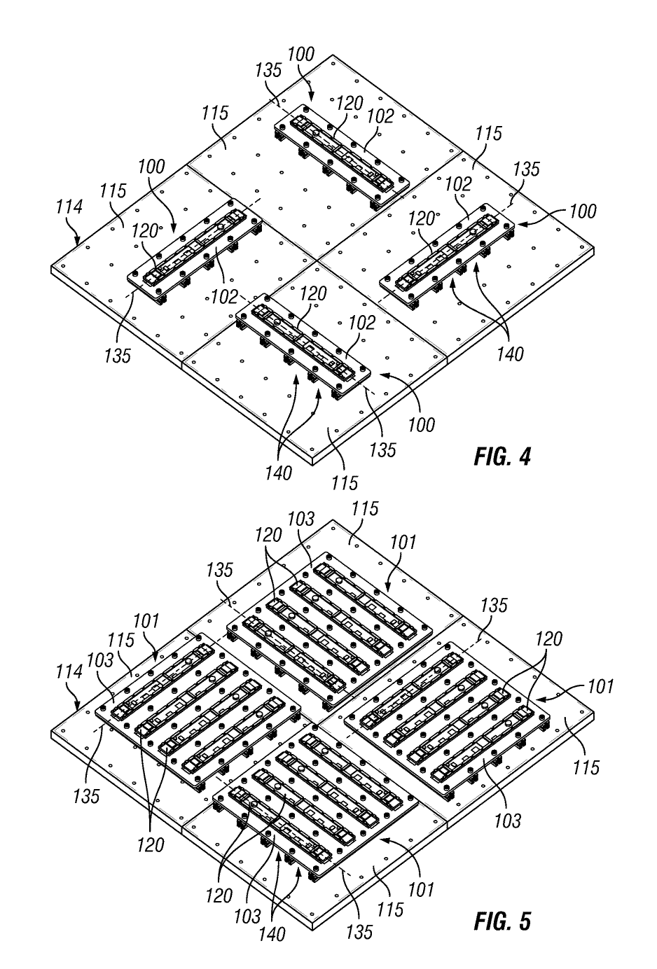

The fixture 100 may be utilized for connecting the PWA 120 to an acceleration table 114 (shown in FIGS. 4 and 5) for subjecting the PWA 120 to HASS testing. The acceleration table 114 may be operable to produce or induce repetitive shocks or pulses (hereinafter referred to as “vibration”) with a multi-axis acceleration response (Gᵣₘₛ) ranging between about five hertz (Hz) and about five kilohertz (kHz) while maintaining low displacement. However, other values for the acceleration response are also within the scope of the present disclosure. The PWA 120 comprises a printed circuit board (PCB) 121 and a plurality of discrete electrical components 123 mounted to the PCB 121. Examples of the discrete components 123 may include integrated circuits (ICs), transformers, inductors, capacitors, field-effect transistors (FETs), metal-oxide-semiconductor FETs (MOSFETs), and other discrete electrical components designed to be mounted to a PCB.

The fixture 100 comprises a member 102, such as a rectangular or other substantially planar plate having a length 104, width 106, and thickness 108. The length 104 may range between about 45 centimeters (cm) and about 65 cm, the width 106 may range between about 15 cm and about 45 cm, and the thickness 108 may range between about 0.5 cm and about 2 cm. However, other values for the length, the width 106, and the thickness 108 are also within the scope of the present disclosure, including in implementations in which the member 102 has a vibration transmissibility factor of less than two and/or a resonant frequency close to or higher than about five kHz. The member 102 may comprise aluminum and/or other thermally conductive material, and may be anodized and/or otherwise surface treated.

The member 102 may comprise a plurality of holes or openings 110 extending therethrough, such as for receiving fasteners 112 for connecting the member 102 to the acceleration table 114 of a HASS, HALT, and/or another testing machine. The member 102 may further comprise another plurality of holes or openings 116 for receiving fasteners 118 for connecting or mounting the PWA 120 to the member 102. The openings 116 may align with a corresponding plurality of holes or openings 117 in the PWA 120, such that the fasteners 118 may extend through both pluralities of holes 116, 117 to connect the PWA 120 to the member 102. The fasteners 112, 118 may comprise screws, bolts, pins, and/or other connecting members.

The member 102 also comprises an opening 122 extending through and along the member 102 between or adjacent the plurality of openings 116. The opening 122 is sized similar to the perimeter of the PWA 120, and is thus elongated along the length 104 of the member 102 similar to the elongated shape of the PWA 120. For example, the opening 122 may have a perimeter substantially conforming to a profile (from the perspective of a plan or top view) or “footprint” of the PWA 120. Thus, the opening 122 may permit a substantial portion of a lower surface of the PWA 120 (facing the acceleration table 114) to be exposed or otherwise not covered by the member 102 when the PWA 120 is connected to the member 102. The opening 122 may be smaller than the profile or outer perimeter of the PWA 120, such as may permit the PWA 120 to be connected to the member 102 without extending into the opening 122. For example, the width 136 of the opening 122 may be smaller than the width 132 of the PWA 120 by an amount ranging between about one percent and about ten percent of the width 132 of the PWA 120, and the length 138 of the opening 122 may be smaller than the length 134 of the PWA 120 by an amount ranging between about one percent and about ten percent of the length 134 of the PWA 120. The opening 122 may be elongated in directions parallel to a longitudinal axis 135 of the PWA 120 and/or the surface of the PWA 120. The opening 122 may also comprise a plurality of individual openings collectively having an aggregate profile as described above.

The fixture 100 may further comprise a plurality of spacers 124 disposed between the acceleration table 114 and the member 102 during HASS testing, such as to maintain the member 102 spaced from the acceleration table 114 by a predetermined amount, which may range between about 1 cm and about 5 cm. Each of the spacers 124 may comprise two or more holes or openings 125 extending though the spacers 124. The openings 125 may be located at opposing ends of each spacer 124 and may align with the openings 110, such as may permit the fasteners 112 to extend through both pluralities of openings 110, 125 to connect the spacers 124 and the member 102 to the acceleration table 114. The spacers 124 may be elongated members extending substantially along the width 106 of the member 102 or otherwise in a direction that is substantially transverse to the length 138 of the opening 122. For example, the spacers 124 may comprise separate or distinct square or rectangular bars, such as lengths of extruded T-slot bars. The height 126 and width 128 of each spacer 124 may be about 2.5 cm, and the length 130 of each spacer 124 may be about equal to the width 106 of the member 102. The spacers 124 may comprise aluminum or other thermally conductive material, and may be anodized or otherwise surface treated. The spacers 124 may also be integral to the member 102, such as in instances when the member 102 and spacers 124 are machined from a single piece of plate, bar, or other stock.

The member 102 and the plurality of spacers 124 may define one or more spaces 140 between the acceleration table 114 and the member 102. The spaces 140 may extend substantially along the width 106 of the member 102 or otherwise in a direction that is substantially transverse to the length 138 of the opening 122 and/or the longitudinal axis 135 of the PWA 120. The spaces 140 may permit substantial airflow on both sides of the PWA 120, and may thus permit uniform heat transfer to both sides of the PWA 120 substantially simultaneously.

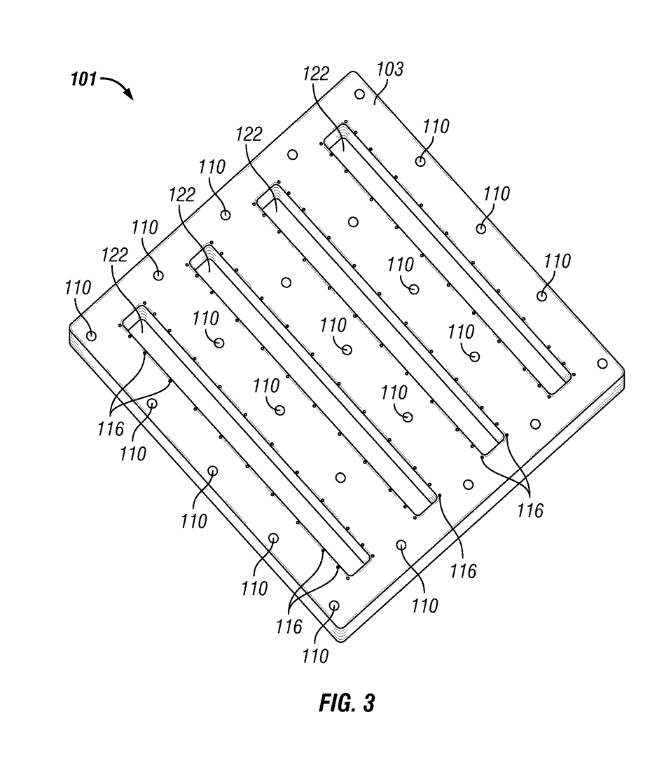

Although FIG. 1 shows the fixture 100 comprising a single opening 122 corresponding to the PWA 120 and a single set of openings 116 for receiving the fasteners 118, the fixture 100 may be implemented comprising additional openings 122 corresponding to the PWA 120 and additional sets of openings 116 for receiving the fasteners 118. FIG. 3 is a perspective view of a portion of an example implementation of such a fixture 101 according to one or more aspects of the present disclosure.

The fixture 101 may comprise a member 103 having four openings 122, each corresponding to a respective instance of a PWA 120, and four sets of openings 116 each for receiving the plurality of fasteners 118. However, it is to be understood that the fixtures 100, 101 shown in FIGS. 1-3 and others within the scope of the present disclosure may comprise two, three, or more openings 122, as well as two, three, or more sets of openings 116, such as may permit the fixtures 100, 101 to receive and/or connect with two, three, or more PWAs 120.

Prior to conducting the HASS testing, one or more fixtures 100, 101 may be connected to the acceleration table 114 (shown in FIGS. 4 and 5). The PWAs 120 may be connected with the fixtures 100, 101 before or after connecting the fixtures 100, 101 to the acceleration table 114.

For example, FIG. 4 is a perspective view of four fixtures 100 each connecting a corresponding PWA 120 with a respective quadrant 115 of the acceleration table 114 according to one or more aspects of the present disclosure. The figure shows each fixture 100 with the member 102 spaced from the acceleration table 114 to form the spaces 140 therebetween, such that the PWAs 120 are spaced from the acceleration table 114 by a predetermined amount, such as about 2.5 cm. Each PWA 120 may be connected to the fixture 100 over a corresponding opening 122 (obstructed from view in FIG. 4 but shown in FIGS. 1 and 2) such that the surfaces of the PWAs 120 facing the acceleration table 114 are exposed to the spaces 140 through the corresponding openings 122. The figure further shows each of the fixtures 100 connected to the acceleration table 114 such that the longitudinal axis 135 of each PWA 120 is substantially perpendicular to the longitudinal axis 135 of another PWA 120 connected to another fixture 100 in the adjoining quadrants 115.

FIG. 5 is a perspective view of another example implementation comprising four fixtures 101 each connecting a plurality of PWAs 120 with each quadrant 115 of the acceleration table 114 according to one or more aspects of the present disclosure. The figure shows each fixture 101 with the member 103 spaced from the acceleration table 114 forming the spaces 140 therebetween, such that each corresponding plurality of PWAs 120 is spaced from the acceleration table 114 by a predetermined amount, such as about 2.5 cm. Each PWA 120 may be connected to the corresponding fixture 101 over a corresponding opening 122 (obstructed from view in FIG. 5 but shown in FIG. 3), such that the surface of each PWA 120 facing the acceleration table 114 is exposed to one or more of the spaces 140 through the corresponding opening 122. The figure further shows each of the fixtures 101 connected to the acceleration table 114 such that the longitudinal axes 135 of each plurality of PWAs 120 are substantially perpendicular to the longitudinal axes 135 of another plurality of PWAs 120 connected to another fixture 101 in the adjoining quadrants 115.

The present disclosure also introduces a universal mounting fixture operable for securing or otherwise connecting one or more PWAs to the acceleration table of the HALT or other testing machine during HASS testing. The fixture may utilize clamps to retain the PWAs, such that the fixture may be insensitive to PWA size variations and may facilitate shorter setup and/or PWA connection time.

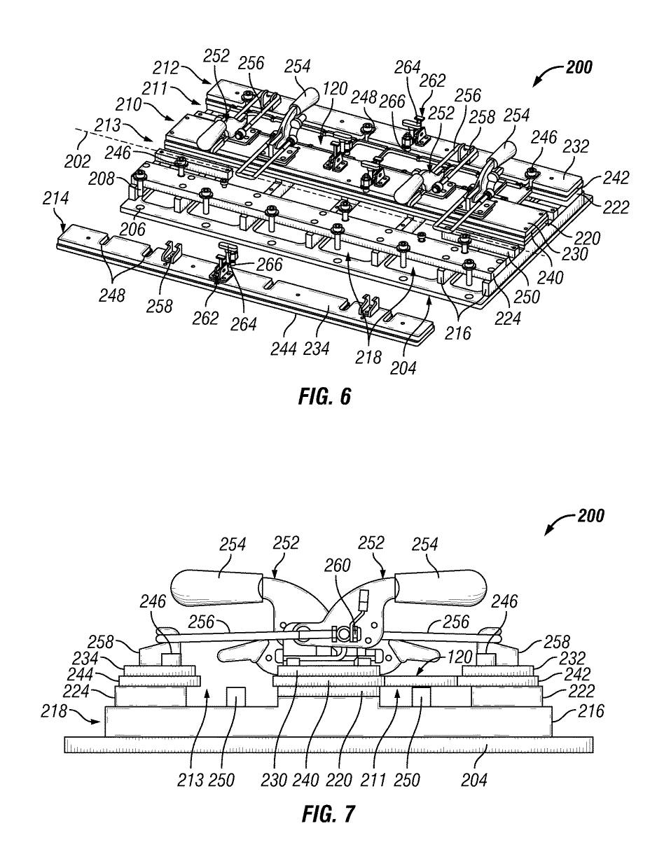

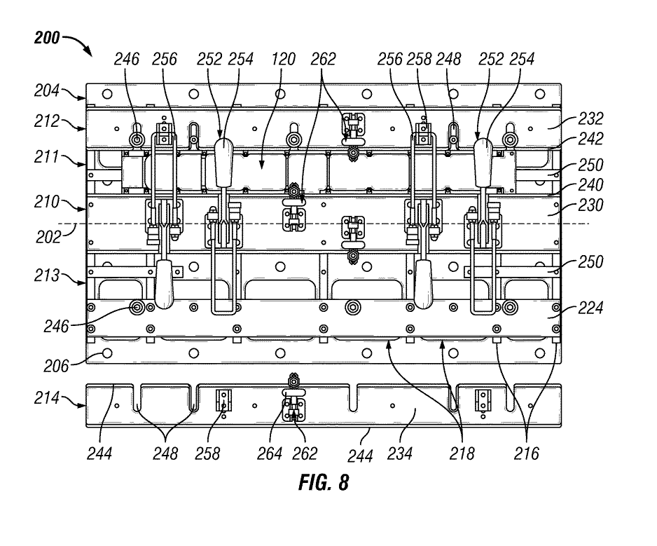

FIG. 6 is a perspective view of at least a portion of an example implementation of such a fixture 200 and the PWA 120 connected with the fixture 200 according to one or more aspects of the present disclosure. FIG. 7 is a side view of a portion of the apparatus shown in FIG. 6, and FIG. 8 is a top view of the apparatus shown in FIG. 6. The fixture 200 may be utilized for connecting one or more PWAs 120 to the acceleration table 114 (shown in FIGS. 4 and 5) for subjecting the PWAs 120 to HASS testing. The following description refers to FIGS. 6-8, collectively.

The fixture 200 comprises a base 204, such as a rectangular or another substantially planar plate or member. The base 204 has a length extending along a longitudinal axis 202 of the fixture 200 and a width extending substantially perpendicular to the longitudinal axis 202. The base 204 may comprise a plurality of holes or openings 206 for receiving fasteners 208 connecting the base 204 to the acceleration table 114. The fasteners 208 may comprise screws, bolts, pins, and/or other connection means.

The fixture 200 also comprises a first plate 210 fixedly disposed relative to the base 204 and elongated in a direction extending along the length of the base 204 in a direction that is substantially parallel to the longitudinal axis 202. A second plate 212 is disposed laterally from the first plate 210 to define a first PWA holding area 211 therebetween. The second plate 212 is elongated in a direction extending along the length of the base 204 in a direction that is substantially parallel to the longitudinal axis 202. The second plate 212 is slidably disposed relative to the base 204, and is thus movable toward and away from the first plate 210. The fixture 200 also comprises a third plate 214 (shown disconnected from the fixture 200) disposed laterally from the first plate 210 and opposite the second plate 212, thus defining a second PWA holding area 213 therebetween. The third plate is elongated in a direction extending along the length of the base 204 in a direction that is substantially parallel to the longitudinal axis 202. The third plate 214 is slidably disposed relative to the base 204, and is thus movable toward and away from the first plate 210.

The fixture 200 also comprises a plurality of spacers 216 extending along the width of the base 204 or otherwise in a direction that is substantially perpendicular to the longitudinal axis 202. The spacers 216 may be disposed between the base 204 and the first, second, and third plates 210, 212, 214, such as to maintain the first, second, and third plates 210, 212, 214 spaced from the base 204 and/or the acceleration table 114 by a predetermined amount, such as about 2.5 cm. The spacers 216 may comprise separate and/or distinct square or rectangular bars. The spacers 216 may also be integral to the base 204, such as in instances when the base 204 and spacers 216 are machined from a single piece of plate, bar, or other stock.

The spacers 216 may be elongated members defining a plurality of spaces 218 extending along the length of the spacers 216 or otherwise in a direction that is substantially perpendicular to the longitudinal axis 202 between the base 204 and the first, second, and third plates 210, 212, 214. The spaces 218 may permit substantial airflow on both sides of the PWA 120 and, thus, permit uniform heat transfer to both sides of the PWA 120 when connected with the fixture 200, as explained below. In an example implementation, the spacers 216 maintain the first, second, and third plates 210, 212, 214 at a predetermined spacing ranging between about 1.5 cm and about 3.5 cm from the base 204.

The fixture 200 also comprises a plurality of intermediate plates 220, 222, 224 fixedly disposed relative to the base 204 and elongated in a direction extending along the length of the base 204 or otherwise in a direction that is substantially parallel to longitudinal axis 202. Each intermediate plate 220, 222, 224 may be fixedly disposed between the plurality of spacers 216 and a corresponding one of the first, second, and third plates 210, 212, 214, respectively. As described above, the second and third plates 212, 214 are movable toward and away from the first plate 210, and the second and third intermediate plates 222, 224 may form or comprise support surfaces for the second and third plates 212, 214 to slide thereon.

Each of the first, second, and third plates 210, 212, 214 may comprise multiple layers of material. First or upper layers 230, 232, 234 of the first, second, and third plates 210, 212, 214, respectively, may comprise a rigid material, such as aluminum, steel, or other metal, which may provide the first, second, and/or third plates 210, 212, 214 with rigidity to permit additional fixture components to be connected thereto. Second or lower layers 240, 242, 244 of the first, second, and third plates 210, 212, 214, respectively, may comprise an elastomeric material, polyether-ether-ketone (PEEK), polytetrafluoroethylene (PTFE), silicone, another polymer, and/or other material that is softer than the material forming the first layers 230, 232, 234. The material forming the second layers 240, 242, 244 may be operable to contact the PWAs 120 to retain the PWAs between the first plate 210 and the second and/or third plates 212, 214 while minimizing cracking, chipping, scratching, or otherwise damaging the PWAs 120. The material forming the second layers 240, 242, 244 may be a thermally insulating material, which may thermally insulate the PWA 120 from the first, second, and/or third plates 210, 212, 214 during HASS testing. The second layers 240, 242, 244 may aid in controlling the temperature of the PWA 120, such as by reducing heat transfer between the PWA 120 and the fixture 200 during HESS testing.

The second layers 240, 242, 244 may cover the edges or lateral surfaces of the first, second, and third plates 210, 212, 214, such as may prevent the first layers 230, 232, 234 from contacting the PWA 120. The second layers 240, 242, 244 may be wider than the first layers 230, 232, 234, whereby the second layers 240, 242, 244 may extend laterally past the first layers 230, 232, 234 to contact the PWA 120 to retain the PWA between the first plate 210 and the second and/or third plates 212, 214. The second layers 240, 242, 244 may coat or cover outer surfaces of the second and third plates 212, 214 to reduce friction between the second plates 212 and the second intermediate plates 222, and between the third plates 214 and the third intermediate plates 224, as the second and third plates 212, 214 slide about the second and third intermediate plates 222, 224.

The fixture 200 also comprises retaining assemblies operable to retain the second and third plates 212, 214 in position. For example, one such retaining assembly may comprise a plurality of elongated openings or slits 248 extending partially along the widths of the second and third plates 212, 214. Such retaining assembly may further comprise a plurality of pins, protrusions, or fasteners 246 fixedly disposed relative to the base 204, wherein each of the plurality of fasteners 246 may be received by a corresponding one of the plurality of slits 248 such that the fasteners 246 may guide the motion of the second and third plates 212, 214 toward and away from the first plate 210. The fasteners 246 may comprise end portions that may be wider than widths of the slits 248, such as may prevent the second and third plates 212, 214 from moving vertically away from the second and third intermediate plates 222, 224, respectively.

The fasteners 246 may be threaded fasteners that may threadedly engage the second and third intermediate plates 222, 224, the base 204, or other portions of the fixture 200 that are fixedly connected with the base 204. When tightened against the second and third plates 212, 214, the fasteners 246 may fixedly restrain or lock the second and third plates 212, 214 against the second and third intermediate plates 222, 224, and/or may fixedly restrain or lock the second and third plates 212, 214 with respect to the base 204, such as to aid in preventing the second and third plates 212, 214 from moving vertically and/or horizontally during the HASS testing.

The fixture 200 may further comprise one or more support members 250 that may vertically support the PWAs 120 in position within the first and second PWA holding areas 211, 213. The support members 250 may be fixedly connected with the spacers 216, and may be positioned between the first and second intermediate plates 220, 222 and between the first and third intermediate plates 220, 224. The support members 250 may be disposed at opposing ends of each PWA holding area 211, 213. The material forming the support members 250 may include PEEK, PTFE, silicone, another polymer, and/or other materials that may support the PWAs 120 while minimizing cracking, chipping, scratching, or otherwise damaging the PWAs 120. The material forming the support members 250 may also be a thermally insulating material, such as to thermally insulate the PWA 120 from the spacers 216 during HASS testing.

The fixture 200 also comprises a plurality of clamps 252 collectively operable to retain a first PWA 120 in the first PWA holding area 211 between the first and second plates 210, 212 and a second PWA (not shown) in the second PWA holding area 213 between the first and third plates 210, 214. The clamps 252 may be toggle latches or over-center latches, such as may comprise a lever 254, an arm 256, and a bracket 258. The main portions or bodies of the clamps 252, comprising the levers 254 and the arms 256, may be connected with the first plate 210, while the brackets 258 may be connected with the second and third plates 212, 214. Prior to HASS testing, the PWAs 120 may be placed on the support members 250 within the PWA holding areas 211, 213, and the arms 256 may be latched over or otherwise engaged with corresponding brackets 258. The levers 254 may then be pulled or otherwise engaged to urge the second plate 212 toward the first plate 210 to clamp the first PWA 120 between the first and second plates 210, 212, and to urge the third plate 214 toward the first plate 210 to clamp the second PWA between the first and third plates 210, 214.

The lengths of the arms 256 may be adjustable to engage the brackets 258 at different positions or distances from the main portions of the clamps 252, which may change due to different sizes of the PWAs 120 undergoing testing. For example, at least a portion of the arms 256 may be threaded, such as may permit a threaded member 260, such as a threaded nut, to be rotated and, thus, extend or retract the arms 256 to different lengths.

The fixture 200 may further comprise a plurality of additional clamps 262 collectively operable to hold down or otherwise retain the first PWA 120 against or in contact with the support members 250 in the first PWA holding area 211 and a second PWA (not shown) in contact with the support members 250 in the second PWA holding area 213. The clamps 262 may be toggle clamps comprising a lever 264 and a hold-down head 266. The clamps 262 may be connected with the first, second, and/or third plates 210, 212, 214 on opposing sides of the PWAs 120. Prior to or after engaging the clamps 252, the PWAs 120 may be held down or otherwise engaged with the clamps 262. To engage the clamps 262, the levers 264 may manually actuated to urge the hold-down head 266 against the PWAs 120 to hold the PWAs 120 in position against the support members 250.

The present disclosure also introduces a methodology comprising a screening process to identify defective PWAs or to weed-out infant mortality failures via HESS testing, which may include different vibration and temperature testing profiles for different categories of PWAs to enhance quality and reliability of downhole electronics. Typical screening processes utilize results from HALT, such as operating and destructive limits of a PWA product line, to then formulate a suitable HASS test profile for the PWA product line. The HASS test profile limits (e.g., temperature and vibration limits) are normally de-rated from the HALT operating and destructive limits. As per industry standards, each PWA product line is subjected to HALT and then a unique HASS test profile is developed for each PWA product line. However, methods according to one or more aspects of the present disclosure may utilize predetermined HASS testing profiles developed based on the different categories of PWAs, and may be implemented without conducting a HALT on a PWA product line prior to conducting the HASS testing.

In an example implementation of the screening process according to one or more aspects of the present disclosure, the PWAs may be categorized or selected as falling into one of three main categories based on the intended operation of the PWA, the type of components mounted on the PWA, and/or the type of mounting technology utilized to mount the components on the PWA. However, other implementations within the scope of the present disclosure may utilize more than three categories.

For example, a first PWA category may include PWAs that primarily operate as central processing unit (CPU) boards, data acquisition boards, controller boards, gauge boards, and/or combinations thereof, a second PWA category may include PWAs that primarily operate as power supply boards, and a the third PWA category may include PWAs that primarily operate as motor driver boards. In another example implementation, the first PWA category may include PWAs in which a majority of the discrete electrical components 123 mounted to the PCB 121 are IC chips, the second PWA category may include PWAs in which a majority of the discrete electrical components 123 mounted to the PCB 121 are transformers, inductors, capacitors, FETs, and/or combinations thereof, and the third PWA category may include PWAs in which a majority of the discrete electrical components 123 mounted to the PCB 121 are MOSFETs. In another example implementation, the first PWA category may include PWAs in which a majority of the discrete electrical components 123 mounted to the PCB 121 are attached to the PCB 121 by surface mounting, the second PWA category may include PWAs in which a majority of the discrete electrical components 123 mounted to the PCB 121 are attached to the PCB 121 via tie-downs and/or soft lead/room-temperature vulcanization (RTV) mounting, and the third PWA category may include PWAs in which a majority of the discrete electrical components 123 mounted to the PCB 121 are attached to the PCB 121 via soft lead/RTV mounting or threaded connectors. For example, the first PWA category may comprise over 90% surface mounted discrete electrical components 123 and less than about 10% of soft lead/RTV mounted discrete electrical components 123 and through-hole mounted discrete electrical components 123.

The PWA categories may also represent combinations of these characteristics. For example, the first PWA category may include PWAs that primarily operate as central processing unit (CPU) boards, data acquisition boards, controller boards, gauge boards, and/or combinations thereof, PWAs in which a majority of the discrete electrical components 123 mounted to the PCB 121 are IC chips, and/or PWAs in which a majority of the discrete electrical components 123 mounted to the PCB 121 are attached to the PCB 121 by surface mounting. Similarly, the second PWA category may include PWAs that primarily operate as power supply boards, PWAs in which a majority of the discrete electrical components 123 mounted to the PCB 121 are transformers, inductors, capacitors, FETs, and/or combinations thereof, and/or PWAs in which a majority of the discrete electrical components 123 mounted to the PCB 121 are attached to the PCB 121 via tie-downs and/or soft lead/RTV mounting. In a like manner, the third PWA category may include PWAs that primarily operate as motor driver boards, PWAs in which a majority of the discrete electrical components 123 mounted to the PCB 121 are MOSFETs, and/or PWAs in which a majority of the discrete electrical components 123 mounted to the PCB 121 are attached to the PCB 121 via soft lead/RTV mounting or threaded connectors.

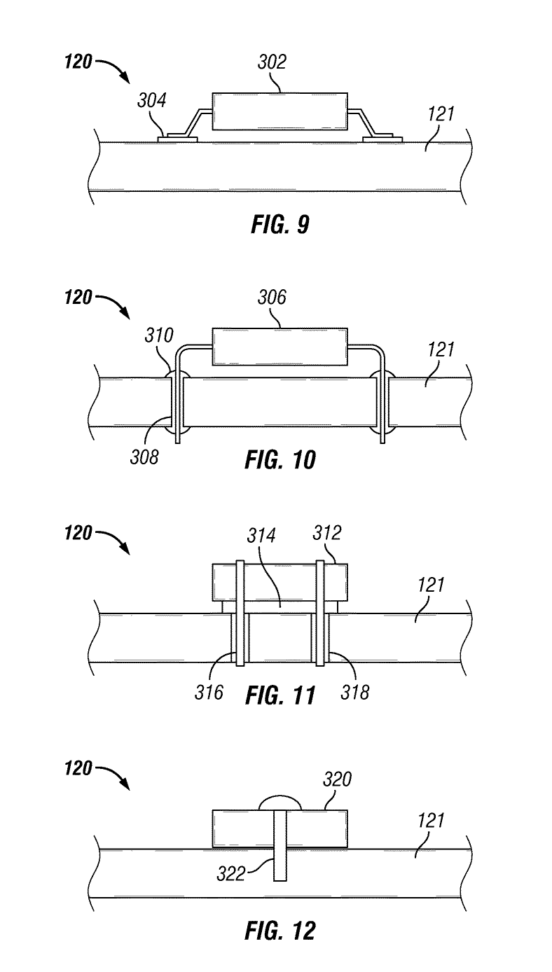

FIGS. 9-12 depict examples of the above-described types of mounting technology utilized to mount the components on the PWA. For example, FIG. 9 is a side view of a portion of an example PWA 120 in which the discrete electrical component 123 is a surface mounted discrete electrical component 302 mounted on the PCB 121 via a solder joint 304. FIG. 10 is a side view of a portion of another example PWA 120 in which the discrete electrical component 123 is a through-hole mounted discrete electrical component 306 mounted in a hole 308 extending through the PCB 121 and retained therein via a solder joint 310. FIG. 11 is a side view of a portion of another example PWA 120 in which the discrete electrical component 123 is a discrete electrical component 312 mounted on the PCB 121 via a soft lead/RTV joint 314. FIG. 11 also depicts tie-downs 316 extending over the discrete electrical component 312 and through holes 318 in the PCB 121 to maintain the discrete electrical component 312 connected with the PCB 121. FIG. 12 is a side view of a portion of another example PWA 120 in which the discrete electrical component 123 is a discrete electrical component 320 mounted to the PCB 121 via a threaded connector 322 extending through a portion of the discrete electrical component 320 and into the PCB 121.

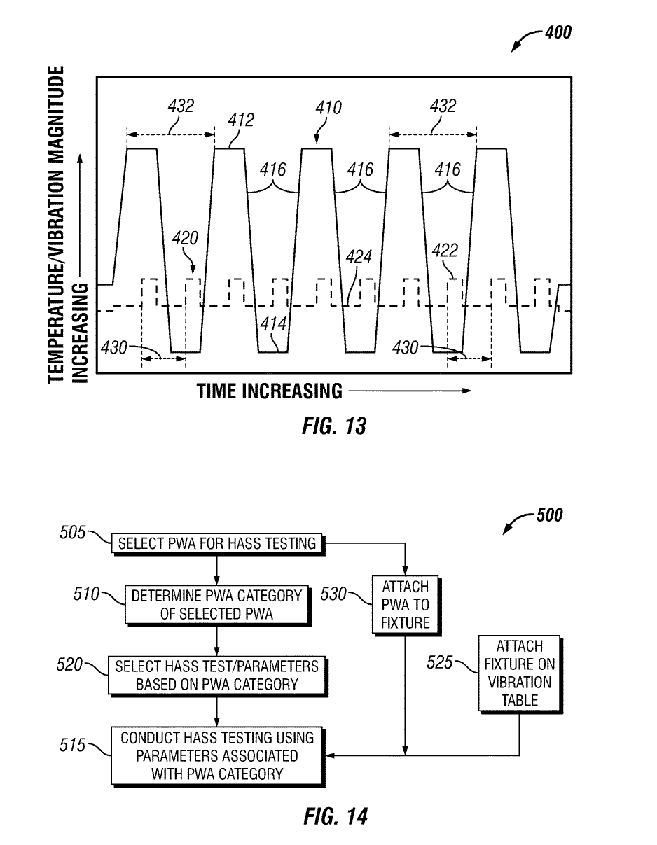

HASS test profiles are predetermined for each PWA category, and each HASS test profile comprises different HASS testing parameters corresponding to the respective PWA category. FIG. 13 is a graph depicting an example HASS test profile 400, which includes a temperature profile 410 and a vibration profile 420. The horizontal axis indicates time from the beginning of the HASS test profile 400 to the end of the HASS test profile 400. The vertical axis indicates temperature of the temperature profile 410 and vibration magnitude of the vibration profile 420 during the HASS testing. An example HASS testing conducted on one or more selected PWAs may range between about two hours and about four hours.

The temperature profile 410 is associated with one of the PWA categories and includes periodic fluctuations of temperature between an upper temperature 412 and a lower temperature 414. The upper and lower temperatures 412, 414 may each be different for one or more of the PWA categories. For example, the upper temperature 412 of the temperature profile 410 corresponding to the above-described first and second PWA categories may range between about 130° C. and about 170° C., and the lower temperature 414 of the temperature profile 410 corresponding to the above-described first and second PWA categories may range between about −50° C. and about −10° C., whereas the upper temperature 412 of the temperature profile 410 corresponding to the above-described third PWA category may range between about 150° C. and about 190° C., and the lower temperature 414 of the temperature profile 410 corresponding to the above-described third PWA category may range between about −70° C. and about −30° C., among other examples also within the scope of the present disclosure.

The upper temperature 412 of the various temperature profiles 410 corresponding to the different PWA categories may range between the rated temperature of the selected PWA and about 10° C. above the rated temperature of the selected PWA, and the lower temperature 414 may range between about −70° C. and about −10° C. Each temperature profile 410 may also comprise transitions 416 between the upper and lower temperatures 412, 414. For example, each transition 416 may be a rate of temperature increase or decrease ranging between about 40° C. per minute and about 80° C. per minute. The temperature profile 410 may comprise maintaining the upper and lower temperatures 412, 414 for periods of time (“temperature dwell times”) ranging between about five minutes and about fifteen minutes. The temperature dwell times for the upper and lower temperatures 412, 414 may be substantially equal.

The vibration profile 420 is also associated with one of the PWA categories and includes periodic fluctuations of vibration magnitude between an upper vibration magnitude 422 and a lower vibration magnitude 424. The upper vibration magnitude 422 may range between about 10 Gᵣₘₛ and about 50 Gᵣₘₛ, and the lower vibration magnitude 424 may range between about 5 Gᵣₘₛ and about 10 Gᵣₘₛ. For example, the vibration profile 420 associated with the above-described first PWA category may have an upper vibration magnitude 422 ranging between about 10 Gᵣₘₛ and about 20 Gᵣₘₛ, the vibration profile 420 associated with the above-described second PWA category may have an upper vibration magnitude 422 ranging between about 35 Gᵣₘₛ and about 50 Gᵣₘₛ, and the vibration profile 420 associated with the above-described third PWA category may have an upper vibration magnitude 422 ranging between about 20 Gᵣₘₛ and about 35 Gᵣₘₛ. The vibration profile 420 may comprise maintaining the upper and lower vibration magnitudes 422, 424 for periods of time (“vibration dwell times”) ranging between about five minutes and about fifteen minutes. The vibration dwell times at the upper vibration magnitude 422 may be substantially less than the vibration dwell times at the lower vibration magnitude 424.

The upper and lower vibration dwell times may be sequential and collectively span instances of a first time period 430, and the upper and lower temperature dwell times may be sequential and collectively span instances of a second time period 432 (perhaps including the depicted temperature transitions 416). As depicted in FIG. 13, instances of the first and second time periods 430, 432 may at least partially overlap.

FIG. 14 is a flow-chart diagram of at least a portion of a method (500) according to one or more aspects of the present disclosure. The method (500) may be performed utilizing at least a portion of one or more implementations of the apparatus shown in one or more of FIGS. 1-12 and/or otherwise within the scope of the present disclosure. Thus, the following description refers to FIGS. 1-12 and 14, collectively.

The method (500) comprises selecting (505) the PWA 120 to be subjected to HASS testing, determining (510) which one of a plurality of predetermined PWA categories includes the selected (505) PWA 120, and conducting (515) the HASS testing on the selected (505) PWA 120 utilizing HASS testing parameters associated with the determined (510) PWA category. The method (500) may exclude conducting a HALT on another PWA that is substantially the same or similar to the selected (505) PWA.

As described above, determining (510) which of the predetermined PWA categories includes the selected (505) PWA 120 may be based on the primary operation of the PWA 120, the types of components mounted on the PWA 120, the means by which the components are mounted on the PWA 120, or a combination thereof. For example, determining (510) which of the predetermined PWA categories includes the selected (505) PWA 120 may comprise: determining that a first PWA category includes the selected (505) PWA 120 if the selected (505) PWA 120 is or comprises a CPU board, a data acquisition board, a controller board, a gauge board, or a combination thereof; determining that a second PWA category includes the selected (505) PWA 120 if the selected (505) PWA 120 is or comprises a power supply board; and determining that a third PWA category includes the selected (505) PWA 120 if the selected (505) PWA 120 is or comprises a motor driver board.

Determining (510) which of the predetermined PWA categories includes the selected (505) PWA 120 may also or instead comprise: determining that a first PWA category includes the selected (505) PWA 120 if each of a majority of the plurality of discrete electrical components 123 mounted to the PCB 121 of the selected (505) PWA 120 is an integrated circuit (IC) chip; determining that a second PWA category includes the selected (505) PWA 120 if each of a majority of the plurality of discrete electrical components 123 mounted to the PCB 121 of the selected (505) PWA 120 is either a transformer, an inductor, a capacitor, or an FET; and determining that a third PWA category includes the selected (505) PWA 120 if each of a majority of the plurality of discrete electrical components 123 mounted to the PCB 121 of the selected (505) PWA 120 is a MOSFET.

Determining (510) which of the predetermined PWA categories includes the selected (505) PWA 120 may also or instead comprise: determining that a first PWA category includes the selected (505) PWA 120 if each of a majority of the plurality of discrete electrical components 123 mounted to the PCB 121 of the selected (505) PWA 120 is attached to the PCB 121 by surface mounting (such as depicted in FIG. 9); determining that a second PWA category includes the selected (505) PWA 120 if each of a majority of the plurality of discrete electrical components 123 mounted to the PCB 121 of the selected (505) PWA 120 is attached to the PCB 121 by a corresponding threaded fastener (such as the threaded fastener 322 shown in FIG. 12); and determining that a third PWA category includes the selected (505) PWA 120 if each of a majority of the plurality of discrete electrical components 123 mounted to the PCB 121 of the selected (505) PWA 120 is attached to the PCB 121 by means other than surface mounting and threaded fasteners (such as depicted in FIGS. 10 and 11).

The method (500) may also comprising selecting (520) the HASS test from a plurality of predetermined HASS tests based on the determined (510) PWA category, wherein each of the plurality of predetermined HASS tests has different HASS testing parameters, and wherein conducting (515) the HASS testing comprises conducting (515) the selected (520) HASS test utilizing the HASS testing parameters that correspond to the selected (520) HASS test.

As described above, conducting (515) the HASS test on the selected (505) PWA 120 may be for a period of time ranging between about two hours and about four hours. The HASS testing parameters comprise the above-described vibration profile 420 associated with the determined (510) PWA category, which defines the periodic fluctuations of vibration magnitude between the upper vibration magnitude 422 and the lower vibration magnitude 424. The HASS testing parameters also comprise the above-described temperature profile 410 associated with the determined (510) PWA category, which defines the periodic fluctuations of temperature between the upper temperature 412 and the lower temperature 414.

Conducting (515) the HASS test may comprise vibrating the selected (505) PWA 120 at the upper vibration magnitude 422 for a first vibration dwell time, vibrating the selected (505) PWA 120 at the lower vibration magnitude 424 for a second vibration dwell time, maintaining the selected (505) PWA 120 at the upper temperature 412 for a first temperature dwell time, and maintaining the selected (505) PWA 120 at the lower temperature 414 for a second temperature dwell time. The first and second vibration and temperature dwell times may each range between about five minutes and about fifteen minutes. However, the first vibration dwell time may be substantially less than the second vibration dwell time. As depicted in FIG. 13, the first and second vibration dwell times may be sequential and collectively span a first time period 430, the first and second temperature dwell times may be sequential and collectively span a second time period 432 (perhaps including the depicted temperature transitions 416), and instances of the first and second time periods 430, 432 may at least partially overlap.

The method (500) may also comprise attaching (525) a fixture to an acceleration table. The fixture may be the fixture 100 shown in FIGS. 1, 2, and 4, the fixture 101 shown in FIGS. 3 and 5, and/or other fixtures within the scope of the present disclosure having a mounting plate or other member 102, 103 having an elongated opening 122 exposing a bottom surface of the selected (505) PWA 120 attached thereto. The acceleration table may be the acceleration table 114 shown in FIGS. 4 and 5 and/or other vibration means within the scope of the present disclosure. The method (500) may also comprise attaching (530) the selected (505) PWA 120 to the mounting plate or other member 102, 103 of the fixture 100, 101 over the elongated opening 122 such that the selected (505) PWA 120 is spaced from the acceleration table 114 and a side of the selected (505) PWA 120 that faces the acceleration table 114 is exposed through the elongated opening 122. Attaching (525) the fixture 100, 101 to the acceleration table 114 and attaching (530) the selected (505) PWA 120 to the fixture 100, 101 may be performed in either order.

Selecting (505) the PWA for the HASS test may comprise selecting a plurality of substantially similar PWAs to be simultaneously subjected to the HASS test. In such implementations, attaching (530) the selected (505) PWA 120 to the fixture 100, 101 may comprise attaching each of the plurality of selected PWAs 120 to a corresponding one of a plurality of fixtures 100, 101, and attaching (525) the fixture 100, 101 to the acceleration table 114 may comprise attaching the plurality of fixtures to the acceleration table 114 such that a longitudinal axis of each of the plurality of PWAs is substantially perpendicular to a longitudinal axis of another of the plurality of PWAs, such as in the example implementation depicted in FIG. 4. Such implementations may also or instead comprise attaching each of a plurality of sets of the plurality of PWAs to a corresponding one of a plurality of fixtures, and attaching each of the plurality of fixtures to the acceleration table 114 such that each of the plurality of sets is oriented about ninety degrees with respect to another of the plurality of sets, such as in the example implementation depicted in FIG. 5.

In view of the entirety of the present disclosure, including the claims and the figures, a person having ordinary skill in the art should readily recognize that the present disclosure introduces an apparatus comprising: a fixture for connecting a PWA to an acceleration table for subjecting the PWA to HASS testing, wherein the fixture comprises: a member; and a plurality of spacers, wherein: a plurality of first openings extend through the member and corresponding ones of the plurality of spacers for receiving first fasteners connecting the member and the plurality of spacers to the acceleration table such that the member is spaced from the acceleration table by the plurality of spacers; a plurality of second openings extend into the member for receiving second fasteners connecting the PWA to the member; and a third opening disposed between ones of the plurality of second openings, wherein the third opening extends through the member and exposes a substantial portion of a surface of the PWA facing the acceleration table.

The member may have a thickness ranging between about 0.5 centimeters and about 2.0 centimeters, such as a thickness of about 1.3 centimeters.

The fixture may be operable for connecting a plurality of PWAs to the acceleration table for subjecting the plurality of PWAs to the HASS testing simultaneously. In such implementations, among others within the scope of the present disclosure, the third opening may be one of a plurality of third openings each exposing a substantial portion of a surface of a corresponding one of the plurality of PWAs facing the acceleration table.

The plurality of spacers may maintain the spacing of the member from the acceleration table at about 2.5 centimeters.

The member and the plurality of spacers may define a plurality of spaces extending between the acceleration table and the member in a direction that is substantially transverse to the third opening.

The member may be a substantially planar plate.

The third opening may be a perimeter substantially conforming to a footprint of the PWA.

The PWA may have a first width in a direction parallel to the surface of the PWA, and the third opening may have a second width that is less than the first width by an amount ranging between about one percent and about ten percent of the first width.

Each of the plurality of spacers may comprise a length of extruded T-slotted bar extending transverse to the third opening and having two of the plurality of first openings at opposing ends.

The present disclosure also introduces an apparatus comprising: a fixture for connecting a PWA to an acceleration table for subjecting the PWA to HASS testing, wherein the fixture comprises: a base having a length, a width, and a height, wherein the base comprises a plurality of openings for receiving fasteners connecting the base to the acceleration table; a first plate fixedly disposed relative to the base and elongated in a direction extending along the length of the base; a second plate slidably disposed relative to the base and elongated in a direction extending along the length of the base, wherein the second plate is movable toward and away from the first plate; a plurality of elongated spacers extending in a direction along the width of the base between the base and the first and second plates for maintaining the first and second plates spaced from the base, wherein the plurality of elongated spacers are fixedly connected with respect to the base and the first plate; and a clamp operable to retain the PWA between the first and second plates.

The clamp may be operable to urge the second plate toward the first plate to clamp the PWA between the first and second plates.

The clamp may be a toggle latch or an over-center latch.

The clamp may comprise a first clamp, and the fixture may further comprise a second clamp, wherein the first clamp may be disposed on the first side of the fixture, and wherein the second clamp may be disposed on the second side of the fixture opposite the first side of the fixture.

The clamp may comprise a clamping arm pivotally connected with the first plate and operable to engage a clamping bracket fixedly connected with the second plate, and length of the clamping arm may be adjustable to engage the clamping bracket at different distances based on the size of the PWA between the first and second plates.

The base, the first and second plates, and the plurality of elongated spacers may collectively define a plurality of spaces extending in a direction along the width of the base.

The fixture may further comprise: a third plate slidably disposed relative to the base, elongated in a direction along the length of the base, and movable toward and away from the first plate, wherein the plurality of elongated spacers may extend between the base and the third plate for maintaining the third plate spaced from the base; and another clamp operable to retain another PWA between the first and third plates.

The fixture may further comprise a retaining assembly operable to retain the second plate in position. In such implementations, among others within the scope of the present disclosure, the retaining assembly may comprise a threaded fastener operable to fixedly restrain the second plate from moving with respect to the base. The retaining assembly may comprise: a plurality of elongated openings extending partially into the second plate; and a plurality of protrusions fixedly disposed relative to the base, wherein each of the plurality of protrusions may be received by a corresponding one of the plurality of elongated openings such that the plurality of protrusions guide the motion of the second plate toward and away from the first plate. At least one of the plurality of protrusions may comprise a threaded fastener operable to fixedly restrain the second plate to prevent the second plate from moving with respect to the base. The threaded fastener may comprise a threaded bolt extending through the second plate, and the threaded bolt may be operable to fixedly restrain the second plate with respect to the base when the threaded bolt is tightened against the second plate.

The fixture may further comprise an intermediate plate fixedly disposed relative to the base and elongated in a direction extending along the length of the base, the intermediate plate may be disposed between the plurality of elongated spacers and the second plate, and the second plate may slide about a surface of the intermediate plate.

The first plate and the second plate may each comprise first and second layers of material. The second layers of material of the first and second plates may contact the PWA to retain the PWA between the first and second plates. The second layers of material may be softer than the first layers of material.

The fixture may further comprise at least one support member fixedly disposed relative to the base between the first and second plates, and the support members may vertically support the PWA in position between the first and second plates. In such implementations, among others within the scope of the present disclosure, the at least one support member may comprise two support members each disposed on opposing sides of the fixture.

The present disclosure also introduces a method comprising: selecting a PWA for a HASS test; determining which one of a predetermined plurality of PWA categories includes the selected PWA; and conducting the HASS test on the selected PWA utilizing HASS testing parameters associated with the determined PWA category.

The selected PWA may be a first PWA, and the method may not comprise conducting a HALT on a second PWA that is substantially the same or similar to the first PWA.

The determining may be based on types of components mounted on the PWA.

The determining may be based on types of mounting of components mounted on the PWA.

The determining may comprise: determining that a first PWA category includes the selected PWA if the selected PWA is or comprises a CPU board, a data acquisition board, a controller board, a gauge board, or a combination thereof; determining that a second PWA category includes the selected PWA if the selected PWA is or comprises a power supply board; and determining that a third PWA category includes the selected PWA if the selected PWA is or comprises a motor driver board.

The selected PWA may comprise a plurality of discrete electrical components attached to a PCB, and the determining may comprise: determining that a first PWA category includes the selected PWA if each of a majority of the plurality of discrete electrical components is an IC chip; determining that a second PWA category includes the selected PWA if each of a majority of the plurality of discrete electrical components is selected from the group consisting of: a transformer, an inductor, a capacitor, and an FET; and determining that a third PWA category includes the selected PWA if each of a majority of the plurality of discrete electrical components is a MOSFET.

The selected PWA may comprise a plurality of discrete electrical components attached to a PCB, and the determining may comprise: determining that a first PWA category includes the selected PWA if each of a majority of the plurality of discrete electrical components is attached to the PCB by surface mounting; determining that a second PWA category includes the selected PWA if each of a majority of the plurality of discrete electrical components is attached to the PCB by a corresponding threaded fastener; and determining that a third PWA category includes the selected PWA if each of a majority of the plurality of discrete electrical components is attached to the PCB by means other than surface mounting and threaded fastener.

The method may further comprise selecting the HASS test from a plurality of predetermined HASS tests based on the determined PWA category. Each of the plurality of predetermined HASS tests may have different HASS testing parameters. The conducting may comprise conducting the selected HASS test utilizing the HASS testing parameters that correspond to the selected HASS test.

Conducting the HASS test on the selected PWA may comprise conducting the HASS test on the selected PWA for a period of time ranging between about two hours and about four hours.

The HASS testing parameters may comprise a vibration profile associated with the determined PWA category and defining periodic fluctuations of vibration magnitude between an upper vibration magnitude and a lower vibration magnitude. For example, the upper vibration magnitude may range between about 15 Grms and about 50 Grms, and the lower vibration magnitude may range between about 5 Grms and about 10 Grms.

The HASS testing parameters may comprise a temperature profile associated with the determined PWA category and defining periodic fluctuations of temperature between an upper temperature and a lower temperature. For example, the upper temperature may range between the rated temperature of the selected PWA and about 10° C. above the rated temperature of the selected PWA, and the lower temperature may range between about −50° C. and about −30° C. The temperature profile may further comprise transitions between the upper and lower temperatures. For example, each transition may be a rate of temperature increase or decrease ranging between about 40° C. per minute and about 80° C. per minute.

The HASS testing parameters may comprise: a vibration profile associated with the determined PWA category and defining periodic fluctuations of vibration magnitude between an upper vibration magnitude and a lower vibration magnitude; and a temperature profile associated with the determined PWA category and defining periodic fluctuations of temperature between an upper temperature and a lower temperature. For example, conducting the HASS test may comprise: vibrating the selected PWA at the upper vibration magnitude for a first period of time; vibrating the selected PWA at the lower vibration magnitude for a second period of time; maintaining the selected PWA at the upper temperature for a third period of time; and maintaining the selected PWA at the lower temperature for a fourth period of time. The first, second, third, and fourth time periods may each range between about five minutes and about fifteen minutes. The first period of time may be substantially less than the second period of time. The first and second periods of time may be sequential and span a fifth period of time, the third and fourth periods of time may be sequential and span a sixth period of time, and the fifth and sixth periods of time may at least partially overlap.

The method may further comprise: attaching a fixture to an acceleration table, wherein the fixture may comprise a mounting plate spaced from the acceleration table and having an elongated opening; and attaching the selected PWA to the mounting plate over the elongated opening such that the selected PWA is spaced from the acceleration table and a side of the selected PWA facing the acceleration table is exposed through the elongated opening.

Selecting the PWA for the HASS test may comprise selecting a plurality of substantially similar PWAs to be simultaneously subjected to the HASS test. In such implementations, the method may further comprise: attaching each of the plurality of PWAs to a corresponding one of a plurality of fixtures; and attaching the plurality of fixtures to an acceleration table such that a longitudinal axis of each of the plurality of PWAs is substantially perpendicular to a longitudinal axis of another of the plurality of PWAs.

Selecting the PWA for the HASS test may comprise selecting a plurality of substantially similar PWAs to be simultaneously subjected to the HASS test, and the method may further comprise: attaching each of a plurality of sets of the plurality of PWAs to a corresponding one of a plurality of fixtures; and attaching each of the plurality of fixtures to an acceleration table such that each of the plurality of sets is oriented about ninety degrees with respect to another of the plurality of sets.

The foregoing outlines features of several embodiments so that a person having ordinary skill in the art may better understand the aspects of the present disclosure. A person having ordinary skill in the art should appreciate that they may readily use the present disclosure as a basis for designing or modifying other processes and structures for carrying out the same functions and/or achieving the same benefits of the embodiments introduced herein. A person having ordinary skill in the art should also realize that such equivalent constructions do not depart from the spirit and scope of the present disclosure, and that they may make various changes, substitutions and alterations herein without departing from the spirit and scope of the present disclosure.

The Abstract at the end of this disclosure is provided to comply with 37 C.F.R. §1.72(b) to permit the reader to quickly ascertain the nature of the technical disclosure. It is submitted with the understanding that it will not be used to interpret or limit the scope or meaning of the claims.

What is claimed is:

1. An apparatus, comprising:
a fixture for connecting a printed wiring assembly (PWA) to an acceleration table for subjecting the PWA to highly accelerated stress screen (HASS) testing, wherein the fixture comprises:
a member; and
a plurality of spacers, wherein:
a plurality of first openings extend through the member and corresponding ones of the plurality of spacers for receiving first fasteners connecting the member and the plurality of spacers to the acceleration table such that the member is spaced from the acceleration table by the plurality of spacers;
a plurality of second openings extend into the member for receiving second fasteners connecting the PWA to the member; and
a third opening disposed between ones of the plurality of second openings, wherein the third opening extends through the member and exposes a substantial portion of a surface of the PWA facing the acceleration table.

2. The apparatus of claim 1 wherein the member and the plurality of spacers define a plurality of spaces extending between the acceleration table and the member in a direction that is substantially transverse to the third opening.

3. The apparatus of claim 1 wherein the third opening has a perimeter substantially conforming to a footprint of the PWA.

4. An apparatus, comprising:
a fixture for connecting a printed wiring assembly (PWA) to an acceleration table for subjecting the PWA to highly accelerated stress screen (HASS) testing, wherein the fixture comprises:
a base having a length, a width, and a height, wherein the base comprises a plurality of openings for receiving fasteners connecting the base to the acceleration table;
a first plate fixedly disposed relative to the base and elongated in a direction extending along the length of the base;
a second plate slidably disposed relative to the base and elongated in a direction extending along the length of the base, wherein the second plate is movable toward and away from the first plate;
a plurality of elongated spacers extending in a direction along the width of the base between the base and the first and second plates for maintaining the first and second plates spaced from the base, wherein the plurality of elongated spacers are fixedly connected with respect to the base and the first plate; and
a clamp operable to retain the PWA between the first and second plates.

5. The apparatus of claim 4 wherein the clamp comprises a clamping arm pivotally connected with the first plate and operable to engage a clamping bracket fixedly connected with the second plate, and wherein length of the clamping arm is adjustable to engage the clamping bracket at different distances based on the size of the PWA between the first and second plates.

6. The apparatus of claim 4 wherein the first plate and the second plate each comprise first and second layers of material, wherein the second layers of material of the first and second plates contact the PWA to retain the PWA between the first and second plates, and wherein the second layers of material are softer than the first layers of material.

7. A method, comprising:
selecting a printed wiring assembly (PWA) for a highly accelerated stress screening (HASS) test;
determining which one of a predetermined plurality of PWA categories includes the selected PWA; and
conducting the HASS test on the selected PWA utilizing HASS testing parameters associated with the determined PWA category.

8. The method of claim 7 wherein the selected PWA is a first PWA, and wherein the method does not comprise conducting a highly accelerated life test (HALT) on a second PWA that is substantially the same or similar to the first PWA.

9. The method of claim 7 wherein the determining is based on types of components mounted on the PWA.

10. The method of claim 7 wherein the determining is based on types of mounting of components mounted on the PWA.

11. The method of claim 7 wherein the determining comprises:
determining that a first PWA category includes the selected PWA if the selected PWA is or comprises a central processing unit (CPU) board, a data acquisition board, a controller board, a gauge board, or a combination thereof;
determining that a second PWA category includes the selected PWA if the selected PWA is or comprises a power supply board; and
determining that a third PWA category includes the selected PWA if the selected PWA is or comprises a motor driver board.

12. The method of claim 7 wherein the selected PWA comprises a plurality of discrete electrical components attached to a printed circuit board (PCB), and wherein the determining comprises:
determining that a first PWA category includes the selected PWA if each of a majority of the plurality of discrete electrical components is an integrated circuit (IC) chip;
determining that a second PWA category includes the selected PWA if each of a majority of the plurality of discrete electrical components is selected from the group consisting of: a transformer, an inductor, a capacitor, and a field-effect transistor (FET); and
determining that a third PWA category includes the selected PWA if each of a majority of the plurality of discrete electrical components is a metal-oxide-semiconductor FET (MOSFET).

13. The method of claim 7 wherein the selected PWA comprises a plurality of discrete electrical components attached to a printed circuit board (PCB), and wherein the determining comprises:
determining that a first PWA category includes the selected PWA if each of a majority of the plurality of discrete electrical components is attached to the PCB by surface mounting;
determining that a second PWA category includes the selected PWA if each of a majority of the plurality of discrete electrical components is attached to the PCB by a corresponding threaded fastener; and
determining that a third PWA category includes the selected PWA if each of a majority of the plurality of discrete electrical components is attached to the PCB by means other than surface mounting and threaded fastener.

14. The method of claim 7 further comprising selecting the HASS test from a plurality of predetermined HASS tests based on the determined PWA category, wherein each of the plurality of predetermined HASS tests has different HASS testing parameters, and wherein the conducting comprises conducting the selected HASS test utilizing the HASS testing parameters that correspond to the selected HASS test.

15. The method of claim 7 wherein the HASS testing parameters comprise:
a vibration profile associated with the determined PWA category and defining periodic fluctuations of vibration magnitude between an upper vibration magnitude and a lower vibration magnitude; and
a temperature profile associated with the determined PWA category and defining periodic fluctuations of temperature between an upper temperature and a lower temperature.

16. The method of claim 15 wherein conducting the HASS test comprises:
vibrating the selected PWA at the upper vibration magnitude for a first period of time;
vibrating the selected PWA at the lower vibration magnitude for a second period of time;
maintaining the selected PWA at the upper temperature for a third period of time; and
maintaining the selected PWA at the lower temperature for a fourth period of time.

17. The method of claim 16 wherein:
the first and second periods of time are sequential and span a fifth period of time;
the third and fourth periods of time are sequential and span a sixth period of time; and
the fifth and sixth periods of time at least partially overlap.

18. The method of claim 7 further comprising:
attaching a fixture to an acceleration table, wherein the fixture comprises a mounting plate spaced from the acceleration table and having an elongated opening; and
attaching the selected PWA to the mounting plate over the elongated opening such that the selected PWA is spaced from the acceleration table and a side of the selected PWA facing the acceleration table is exposed through the elongated opening.

19. The method of claim 7 wherein selecting the PWA for the HASS test comprises selecting a plurality of substantially similar PWAs to be simultaneously subjected to the HASS test, and wherein the method further comprises:
attaching each of the plurality of PWAs to a corresponding one of a plurality of fixtures; and
attaching the plurality of fixtures to an acceleration table such that a longitudinal axis of each of the plurality of PWAs is substantially perpendicular to a longitudinal axis of another of the plurality of PWAs.

20. The method of claim 7 wherein selecting the PWA for the HASS test comprises selecting a plurality of substantially similar PWAs to be simultaneously subjected to the HASS test, and wherein the method further comprises:
attaching each of a plurality of sets of the plurality of PWAs to a corresponding one of a plurality of fixtures; and
attaching each of the plurality of fixtures to an acceleration table such that each of the plurality of sets is oriented about ninety degrees with respect to another of the plurality of sets.
